(19) United States
(12) Patent Application Publication
(10) Pub. No.: US 2015/0140490 A1
(43) Pub. Date: May 21, 2015

(54) OVERLAY FILM FORMING COMPOSITION AND RESIST PATTERN FORMATION METHOD USING SAME

(71) Applicant: AZ ELECTRONIC MATERIALS (LUXEMBOURG) S.a.r.l., Somerville, NJ (US)

(72) Inventors: Xiaowei Wang, Shizuoka (JP); Masato Suzuki, Shizuoka (JP); Georg Pawlowski, Shizuoka (JP)

(21) Appl. No.: 14/395,885

(22) PCT Filed: Jun. 5, 2013
(86) PCT No.: PCT/JP2013/065626

§ 371 Date: Oct. 21, 2014

(30) Foreign Application Priority Data
Jun. 7, 2012 (JP) 2012-130111

(51) Int. Cl. G03F 7/038; G03F 7/30; G03F 7/20; H01L 21/027

(52) U.S. Cl. CPC G03F 7/0388; H01L 21/0271; G03F 7/30; G03F 7/2002
USPC 430/285.1; 430/325; 430/287.1

(57) ABSTRACT

An object of the present invention is to provide a composition enabling to form a topcoat layer capable of preventing outgassing and of keeping deep UV light from impairing pattern shape in a lithographic process with extreme UV light. The object can be achieved by a composition of the invention for forming a topcoat layer. The composition contains a water-soluble polymer comprising hydrophilic groups and deep-UV absorbing groups absorbing light of 170 to 300 nm, and an aqueous solvent. The solvent comprises 70 weight % or more of water. The composition is cast on a resist layer and heated to harden, and thereafter the resist layer is subjected to exposure by use of extreme UV light and then developed to form a pattern.

### TECHNICAL FIELD

The present invention relates to a composition for forming a topcoat layer used in a photolithographic process. In detail, this invention relates to a composition for forming a topcoat layer that is provided on a resist layer before the resist layer is exposed to extreme UV light for producing a resist pattern in a photolithographic process. Further, the invention also relates to a pattern formation method using that composition for forming a topcoat layer.

### BACKGROUND ART

According to a recent trend toward downsizing of various devices, there have been strong demands for high integration of semiconductor ICs and hence resist patterns have been required to be made more and more minute so as to meet the demands. In order to satisfy this requirement, it is necessary to adopt a photo-lithographic process including exposure to light in a shorter wavelength range. The light for exposure has become shorter and shorter in wavelength, and has changed from visible light to UV or far UV light. Further, the exposure is now often carried out by use of extreme UV light. For example, in manufacture of semiconductor devices such as ICs and LSIs, specifically, in production processes of DRAMs, flash memories and logic semi-conductor devices, it is required to form ultrafine patterns and hence lithography with extreme UV light is becoming more and more important.

To cope with the above requirement, many resist compositions have been developed that are sensitive to light in various wavelength ranges. Among them, commercially available chemically amplified resist compositions have been hitherto thought to be mostly employable in a photolithographic process with extreme UV light. For example, common resist compositions for KF or ArF laser exposure have been regarded as also usable in a lithographic process including exposure to extreme UV light. Actually, however, there remain many problems needed to improve in view of resolution, sensitivity, roughness, and so on.

On the other hand, there also remain problems of light sources and masks in exposure apparatuses, and those problems are reasons why lithography technique with extreme UV light has not yet been widely employed in practice. It has been thought that resist pattern shapes are impaired by longer wavelength light, particularly, deep UV light of, for example, 193 nm or 248 nm, contained in emission from extreme UV light sources. When resist compositions for KF or ArF laser exposure are used as described above in a lithographic process with extreme UV light, they are sensitively made to react not only by extreme UV light but also, of course, by deep UV light in a longer wavelength range than extreme UV light.

Extreme UV light sources generally emit extreme UV light together with longer wavelength light, such as deep UV light. Accordingly, when a fine pattern is intended to be formed according to a lithographic process by use of extreme UV light, it is preferred to adopt a light source less emitting the longer wavelength light. In general, the way of generating extreme UV light is controlled, for example, optical systems are regulated so as to remove deep UV light from emission of light sources. It is, however, very difficult to remove deep UV light completely from emission of conventional light sources, and hence it has been impossible in conventional exposure apparatuses to reduce the ratio of deep UV light down to 3% or less in exposure light. Since deep UV light thus contained in emission from extreme UV light sources causes impairment of resist patterns in view of roughness and pattern shape, it has been desired to improve this problem.

Meanwhile, the exposure to extreme UV light is generally carried out under high vacuum conditions. Accordingly, when a resist layer is subjected to the exposure in a lithographic process, it often gives off gases of volatile substances, which are low molecular weight compounds formed by photochemical reactions and/or components of the resist composition contained in the resist layer, such as, photosensitive materials and photo acid-generating agents. Those gases are referred to as “outgases”, and they often stain photo-masks and/or optical elements such as mirrors to degrade the exposure accuracy. Accordingly, it has been also desired to prevent the resist layer from releasing gases.

As a means for solving the above problems, it is proposed to form a topcoat layer on the top surface of a resist layer so as both to absorb deep UV light and to keep the resist layer from giving off gases (Patent documents 1 and 2).

### PRIOR ART DOCUMENTS

[Patent document 1] Japanese Patent Laid-Open No. 2004-348133
[Patent document 2] U.S. Patent Publication No. 2012/21555

### DISCLOSURE OF INVENTION

### Problem to be Solved by the Invention

However, there is generally an organic solvent contained in a conventional composition for forming a topcoat layer. The organic solvent is liable to damage the resist layer laid just under the topcoat layer and consequently to impair the pattern shape. Further, besides the organic solvent, the composition also contains components less different in polarity from the resist layer, and accordingly the resist layer is also liable to suffer from intermixing, namely, from contamination caused at the interface by mixing of components of the topcoat layer and the resist layer. Accordingly, it is an object of the present invention to provide such a composition for forming a topcoat layer as can improve the above problems.

### Means for Solving Problem

The present invention resides in a composition for forming a topcoat layer on the top surface of a resist layer, containing

a water-soluble polymer comprising hydrophilic groups and deep-UV absorbing groups that absorb light in the wavelength range of 170 to 300 nm, and

an aqueous solvent,

wherein said aqueous solvent comprises 70% or more of water based on the total weight of said aqueous solvent.

The present invention also resides in a pattern formation method comprising the steps of:

casting a resist composition on a substrate, to form a resist layer,

coating the resist layer with the above composition for forming a topcoat layer,

heating to harden the composition for forming a topcoat layer,

subjecting the resist layer to exposure by use of extreme UV light, and

developing the exposed resist layer.

### Effect of the Invention

The present invention provides a composition capable of forming a topcoat layer which can protect a resist pattern from impairment in roughness and in pattern shape and also which can prevent a resist layer from releasing gases in a photolithographic process for pattern formation including exposure to extreme UV light. Further, the pattern formation method of the present invention enables to produce a minute pattern accurately without staining the exposure apparatus with gases given off from the resist layer.

### BEST MODE FOR CARRYING OUT THE INVENTION

Embodiments of the present invention are described below in detail.

The composition according to the present invention is used for forming a topcoat layer on the top surface of a resist layer. This composition contains a water-soluble polymer comprising hydrophilic groups and deep-UV absorbing groups that absorb light in the wavelength range of 170 to 300 nm, mainly 193 to 248 nm (hereinafter, light in that wavelength range is often referred to as “deep UV light”).

In the present invention, the above polymer has the following three functions:

(1) function as a film-forming component to form a topcoat layer,

(2) function of absorbing and removing deep UV light contained in light applied to the resist layer in exposure, and

(3) function of preventing gases generated in the resist layer from leaking out into atmosphere in exposure.

Any polymer can be selected to use in the present invention without restrictions on the structure thereof, as long as it fulfills the above three functions. The polymer is concretely explained below.

In view of the function as a film-forming component, polymer compounds are generally selected to use. However, although the polymer compounds include natural polymers, it is necessary in the present invention to specify the structure thereof as described later. Accordingly, in the present invention, the water-soluble polymer is a synthetic polymer compound comprising particular repeating units, namely, a particular co-polymer or homo-polymer.

There is no particular restriction on the type of the polymer, and in other words, there is no particular restriction on how monomers are polymerized. The polymer may be formed by any polymerization reaction such as condensation polymerization, ring-opening polymerization or addition polymerization, but is preferably formed by addition polymerization of monomers having vinyl groups.

The water-soluble polymer used in the present invention comprises both hydrophilic groups and deep-UV absorbing groups. Each of those groups may be connected to any position of the monomers. Accordingly, the polymer may be formed either by polymerization of monomers having hydrophilic groups and other monomers having deep-UV absorbing groups or by polymerization of monomers having both hydro-philic groups and deep-UV absorbing groups.

In the case where the water-soluble polymer is a co-polymer formed by co-polymerization of monomers having deep-UV absorbing groups and other monomers having hydrophilic groups, the co-polymer may be in the form of a random polymer or a block polymer. Further, the co-polymer is not restricted to an addition polymer and may be a graft polymer. It is also possible to incorporate co-monomers having neither deep-UV absorbing groups nor hydrophilic groups in the above co-polymerization.

Further, the water-soluble polymer may be formed by polymerization of monomers having both hydrophilic groups and deep-UV absorbing groups. In that case, each of those groups may be connected in any form to the monomer. For example, if the polymer is formed by polymerization of vinyl monomers, each of the hydro-philic group and the deep-UV absorbing group may be independently connected directly to the vinyl group of the monomer, or otherwise the hydrophilic group may be connected via the deep-UV absorbing group to the vinyl group of the monomer. Further, the deep-UV absorbing group may be connected via the hydrophilic group to the vinyl group of the monomer.

In the case where the water-soluble polymer is formed by polymerization of monomers having both hydrophilic groups and deep-UV absorbing groups, the polymer may be either a homo-polymer derived from only those monomers or a co-polymer derived from those monomers and other co-monomers. The co-monomers may be monomers having deep-UV absorbing groups, monomers having hydrophilic groups or monomers having neither deep-UV absorbing groups nor hydrophilic groups.

In the above description, monomers for forming the water-soluble polymer are categorized based on whether or not the hydrophilic groups and the deep-UV absorbing groups are included therein. However, two or more kinds of monomers in the same category can be used in combination. For example, it is possible to use in combination such two kinds of the monomers having deep-UV absorbing groups as absorb UV light in different wavelength ranges. Further, among the monomers having both hydrophilic groups and deep-UV absorbing groups, two kinds of the monomers different only in the hydrophilic groups can be selected to use in combination.

The term “deep-UV absorbing groups” in the present invention means groups that absorb light in the wavelength range of 170 to 300 nm. Examples thereof include aromatic groups, particularly, phenyl, naphthyl and anthracenyl. Those groups may have substituents, if needed. Examples of the substituents include hydro-carbon groups such as alkyl groups. It is preferred for the substituent hydrocarbon group not to contain too many carbon atoms so that the polymer may be water-soluble, and hence the substituent hydrocarbon group contains preferably 10 or less carbon atoms. Examples of the substituents also include hydroxyl and carboxyl, which can serve as the hydrophilic groups.

The substituents may have structures containing phenyl, naphthyl or anthracenyl, and those can serve as the deep-UV absorbing groups. Concrete examples of the substituents include groups having biphenyl skeleton, pyrene skeleton, carbazole skeleton, xanthone skeleton and phenolphthalein skeleton. Even if further having substituents, the groups having those skeletons can serve as the deep-UV absorbing groups.

Examples of the deep-UV absorbing groups are shown below:

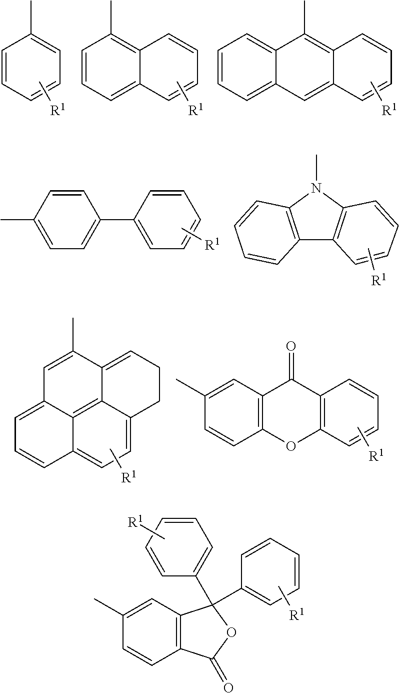

In the above formulas, R¹ is a substituent selected from the group consisting of hydrogen, hydrocarbon groups, hydroxyl and carboxyl.

The term “hydrophilic groups” in the present invention means groups that enable the water-soluble polymer to dissolve in water. The hydrophilic groups are generally well known, and examples thereof include hydroxyl, carboxyl, sulfo, substituted and unsubstituted amino groups, substituted and unsubstituted ammonium groups, carboxylic acid ester groups, sulfonic acid ester groups, substituted and unsubstituted amide groups, alkyleneoxide groups, and oxime groups. Among them, hydroxyl and carboxyl are particularly preferred. Those groups may have substituents, which may be aliphatic hydrocarbon groups such as alkyl groups or aromatic groups such as phenyl groups. If the substituents are aromatic groups, they may serve as the deep-UV absorbing groups.

In the present invention, the hydrophilic groups contribute not only to improving water solubility of the polymer but also to preventing outgassing. That is because most hydrophilic groups can form hydrogen bonds, which make the topcoat layer so dense that gases generated in the resist layer hardly ooze out. Meanwhile, when the resist layer is subjected to exposure, the exposure light liberates protective groups contained the resist resin, cations contained in the photo acid-generating agents and amines contained in the resist composition. Those liberated substances leak out in the form of outgases. However, the hydrophilic groups can catch the liberated substances, and hence this is presumed to be another reason why outgases hardly penetrate through the topcoat layer. Thus, the hydrophilic groups improve the problem of outgassing.

Examples of the hydrophilic groups are shown below:

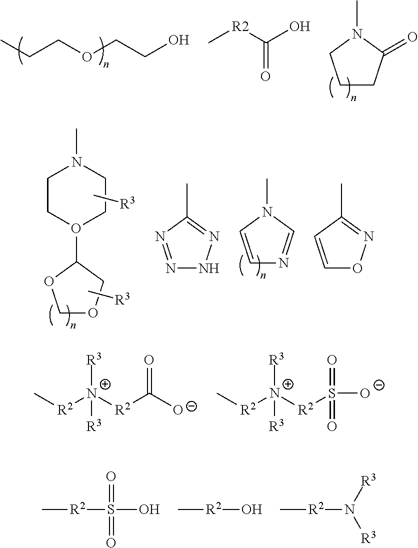

In the above formulas, R² is a divalent linking group such as single bond, substituted or unsubstituted hydrocarbon chain, ether bond, amide bond or ester bond; and R³ is a substituent selected from the group consisting of hydrogen, hydrocarbon groups, hydroxyl and carboxyl. If there are plural R³s in the formula, they may be the same or different from each other.

Examples of monomers capable of forming repeating units having the above hydrophilic groups include: acrylic acid, methacrylic acid, vinyl alcohol, vinylpyrrolidone, acrylic esters and methacrylic esters. Examples of the acrylic esters and methacrylic esters include: acrylic acid hydroxyethyl ester, acrylic acid polyethylene oxide adduct, methacrylic acid hydroxyl-ethyl ester, and methacrylic acid polyethylene oxide adduct.

As described above, the water-soluble polymer used in the present invention is not restricted on the structure, as long as it comprises hydrophilic groups and deep-UV absorbing groups. However, in consideration of treatability and production easiness, the polymer is preferably represented by the following formula (I):

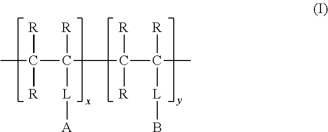

wherein A is a deep-UV absorbing group; B is a hydro-philic group; each R is independently hydrogen or a hydrocarbon group of 1 to 3 carbon atoms provided that plural Rs may be the same or different from each other; each L is independently a divalent linking group provided that plural Ls may be the same or different from each other; and each of x and y is a number indicating the molar ratio of each repeating unit. There is no particular restriction on the arrangement of the repeating units having deep-UV absorbing groups and those having hydrophilic groups, and accordingly the polymer may be a random co-polymer or a block co-polymer.

The above water-soluble polymer is a co-polymer formed by polymerization of monomers having deep-UV absorbing groups and other monomers having hydro-philic groups. In the formula (I), A and B correspond to the aforementioned deep-UV absorbing group and the aforementioned hydrophilic group, respectively; and L is a divalent linking group via which A or B connects to the main chain of the monomer. The linking group L is, for example, single bond, ether bond, imide bond, amide bond or carboxylato bond. Among them, imide bond, amide bond and carboxylato bond are capable of serving as the hydrophilic groups.

In the formula (I), two or more kinds of the repeating units having deep-UV absorbing groups or of those having hydrophilic groups may be contained in combination. For the purpose of absorbing deep UV light in a wide wavelength range, the polymer preferably comprises a combination of repeating units that can absorb deep UV light in different wavelength ranges. For example, it is preferred to contain repeating units having phenyl groups, which absorb deep UV light in a relatively long wavelength range, together with other repeating units having anthracenyl groups, which absorb deep UV light in a relatively short wavelength range.

In the formula (I), x and y are numbers indicating the molar ratios of the repeating units having deep-UV absorbing groups and of those having hydrophilic groups, respectively. If there are repeating units having both deep-UV absorbing groups and hydrophilic groups, they are regarded as the repeating units having A in the formula (I). This means that the repeating units having B in the formula (I) represent repeating units not having deep-UV absorbing groups but having hydrophilic groups. If the polymer comprises two or more kinds of the repeating units having deep-UV absorbing groups or of those having hydrophilic groups, x and y are determined based on the total molar ratios thereof.

The formula (I) does not contain repeating units having neither deep-UV absorbing groups nor hydrophilic groups, and in that case the total of x and y corresponds to 100 mol % and the ratio of x:y is in the range of generally 1:99 to 100:0, preferably 5:95 to 50:50. In the case where x is equal to 100 mol %, the repeating units having A represent repeating units having both deep-UV absorbing groups and hydrophilic groups. Accordingly, in that case, water-solubility of the polymer is attributed to the hydrophilic groups contained in the repeating units having A.

All the repeating units may have both deep-UV absorbing groups and hydrophilic groups. However, since it is relatively difficult to attach a hydrophilic group to a deep-UV absorbing aromatic ring, the polymer is liable to be less soluble in water. Further, the polymer comprising hydrophilic groups attached to deep-UV absorbing aromatic rings is similar in polarity to resist resins. Accordingly, when the topcoat layer is formed on a resist layer, intermixing often occurs at the interface to impair the pattern shape. In contrast, if the polymer is formed by co-polymerization of monomers having deep-UV absorbing groups and other monomers having hydrophilic groups, it is easy to control both deep-UV absorbability and water-solubility of the co-polymer by adjusting their molar ratios. Further, since that co-polymer is relatively very different in polarity from resist resins, there is not much fear of intermixing. Furthermore, it is possible to increase the amount of hydrophilic groups and thereby to improve the problem of outgassing. For those reasons, y in the formula (I) is preferably not 0, further preferably 50 mol % or more, furthermore preferably 70 mol % or more.

Besides the repeating units shown in the formula (I), the water-soluble polymer may also comprise repeating units having neither deep-UV absorbing groups nor hydrophilic groups unless they degrade the effect of the present invention. In the case where the polymer comprises them, the amount thereof is preferably 50 mol % or less, further preferably 30 mol % or less based on the total amount of all the repeating units constituting the polymer.

Shown below are preferred examples of the water-soluble polymer usable in the present invention.

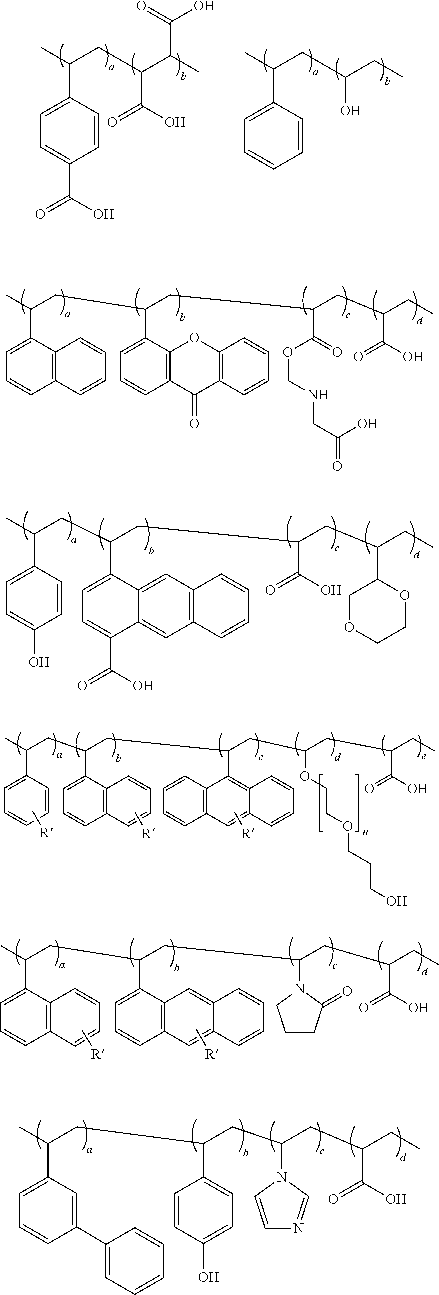

In the above formulas, R′ may be any substituent and is, for example, hydrogen, a hydrocarbon group, hydroxyl, carboxyl or amino; each of a, b, c, d and e is a number indicating the molar ratio of each repeating unit; and n represents a polymerization degree.

The water-soluble polymer used in the present invention preferably has a molecular weight enough to fulfill the function of film-forming. Accordingly, the weight average molecular weight thereof is preferably 1000 or more, further preferably 3000 or more. On the other hand, however, in order to ensure coatability of the composition for forming a topcoat layer, the molecular weight is preferably not too large. Accordingly, the water-soluble polymer used in the present invention preferably has a weight average molecular weight of preferably 30000 or less, more preferably 20000 or less.

As described later, the composition of the present invention for forming a topcoat layer contains water as a solvent. In addition, the formed topcoat layer must be easily removed in development. Accordingly, the water-soluble polymer needs to have sufficient water-solubility, which is preferably 0.1 g/100 cc or more, further preferably 0.5 g/100 cc or more at 25° C. The water-solubility of the polymer must be thus large enough, but there is no upper limit to it.

The content of the water-soluble polymer is adjusted according to the aimed thickness of the topcoat layer, but is normally 0.1 to 10 wt %, preferably 0.5 to 5 wt % based on the total weight of the composition for forming a topcoat layer. If the composition contains the polymer too much, the resultant topcoat layer may be so thick as to absorb a large amount of extreme UV light. That should be paid attention to.

The composition according to the present invention for forming a topcoat layer comprises an aqueous solvent. The aqueous solvent comprises 70 weight % or more of water based on the total weight of the aqueous solvent. In general, the composition is directly cast on a resist layer and therefore is required not to affect the resist layer so negatively as to cause impairment in pattern shape or the like. In view of that, aqueous solvent less affects the resist layer negatively and hence is adopted as the solvent. Water used in the aqueous solvent is preferably purified by distillation, ion-exchange treatment, filtration treatment or various adsorption treatments to remove organic impurities, metal ions and the like.

For improving solubility of the components in the composition, the aqueous solvent containing 30 weight % or less of organic solvent may be used as the solvent unless it degrades the effect of the present invention. Examples of the organic solvent usable in the mixed solvent include: (a) hydrocarbons, such as n-hexane, n-octane, and cyclohexane; (b) alcohols, such as methanol, ethanol, iso-propanol; (c) ketones, such as acetone and methyl ethyl ketone; (d) esters, such as methyl acetate, ethyl acetate and ethyl lactate; (e) ethers, such as diethyl ether and dibutyl ether; (f) other polar solvents, such as dimethylformamide, dimethyl sulfoxide, methyl cellosolve, cellosolve, butyl cellosolve, cellosolve acetate, alkyl cellosolve acetate, butyl carbitol and carbitol acetate. Among them, preferred are alcohols having 1 to 20 carbon atoms, particularly, methanol, ethanol and iso-propanol, which hardly affect the resist layer negatively.

The composition of the present invention for forming a topcoat layer can further contain basic compounds, if necessary, unless they degrade the effect of the invention. In the case where the water-soluble polymer comprises acidic groups, the basic compounds act on them to form salts and thereby to improve solubility of the polymer. This means that the basic compounds enable to increase the content of the water-soluble polymer in the composition so as to form a thicker topcoat layer. Examples of the basic compounds include: tetramethylammonium hydroxide; and amines such as ammonia, alkanol amines (e.g., monoethanol amine), alkyl amines and aromatic amines.

The composition according to the present invention for forming a topcoat layer may furthermore contain other additives, which are intended, for example, for enhancing coatability of the composition onto the resist layer and for improving characteristics of the formed topcoat layer. The additives are, for example, surfactants. Examples of the surfactants include: (a) anionic surfactants, such as, alkyl diphenyl ether disulfonic acid, alkyl diphenyl ether sulfonic acid, alkyl benzene disulfonic acid, polyoxyethylene alkyl ether sulfonic acid, alkyl sulfonic acid, and ammonium salts and organic amine salts thereof; (b) cationic surfactants, such as, hexadecyl trimethyl ammonium hydroxide; (c) nonionic surfactants, such as, polyoxyethylene alkyl ethers (e.g., polyoxyethylene lauryl ether, polyoxy-ethylene oleyl ether, polyoxyethylene cetyl ether), polyoxyethylene fatty acid diester, polyoxyethylene fatty acid monoester, polyoxyethylene-polyoxypropylene block copolymer, and acetylene glycol derivatives; and (d) amphoteric surfactants, such as, 2-alkyl-N-carboxy-methyl-N-hydroxyethyl imidazolinium betaine, lauric acid amide propyl hydroxyl sulfone betaine. However, it should be noted that those examples by no means constitute an exhaustive list of surfactants usable in the present invention. Other additives are, for example, thickening agents, colorants such as dyes, acids and bases. The amount of each additive is determined in consideration of the effect thereof, but is normally 0.01 to 1 wt %, preferably 0.1 to 0.5 wt % based on the total weight of the composition.

The composition according to the present invention for forming a topcoat layer can be used in the same manner as a conventional composition for forming a topcoat layer or for forming a top anti-reflection coating. This means that it is unnecessary to change the production process drastically when patterns are formed by use of the composition of the present invention. The following describes concretely the pattern formation method using the composition of the present invention for forming a topcoat layer.

First, a resist composition is cast on a surface, which may be pretreated, if necessary, of a substrate such as a silicon substrate or a glass substrate according to a known coating method such as spin-coating method, to form a resist composition layer. Prior to the coating of the resist composition, an undercoating layer may be beforehand formed under the resist composition layer by coating. The undercoating layer can improve adhesion between the resist layer and the substrate. Further, if containing transition metals or oxides thereof, the undercoating layer can enhance reflected light to improve the exposure margin.

The pattern formation method of the present invention can employ any one selected from known resist compositions sensitive to extreme UV light. At present, it is general to use a resist composition for deep UV exposure, such as, a photoresist composition for ArF or KrF laser exposure. In the pattern formation method according to the present invention, any resist composition can be selected to use without limitation as long as it has sensitivity to extreme UV light. However, particularly preferred are positive- and negative-working chemically amplified resist compositions.

Either positive- or negative-working chemically amplified resist composition can be used in the pattern formation method of the present invention. The chemically amplified resist composition generates an acid when exposed to radiation, and the acid serves as a catalyst to promote chemical reaction by which solubility to a developer is changed within the areas irradiated with the radiation to form a pattern. For example, the chemically amplified resin composition comprises an acid-generating compound, which generates an acid when exposed to radiation, and an acid-sensitive functional group-containing resin, which decomposes in the presence of acid to form an alkali-soluble group such as phenolic hydroxyl or carboxyl group. The composition may comprise an alkali-soluble resin, a crosslinking agent and an acid-generating compound.

Subsequently, according to, for example, spin-coating, the resist layer thus formed on the substrate is coated with the composition of the present invention for forming a topcoat layer. The applied composition is then heated to evaporate the solvent and thereby to form a topcoat layer. This heating is carried out by means of, for example, a hot-plate. The temperature of heating is determined according to the solvent of the composition, but is normally 25 to 150° C., preferably 80 to 130° C., further preferably 90 to 110° C. The topcoat layer thus formed has a thickness of normally 1 to 100 nm, preferably 5 to 50 nm.

The resist layer may be heated alone to harden immediately after formed on the substrate, and then the composition for forming a topcoat layer can be cast thereon and heated.

The topcoat layer thus formed is highly trans-parent to extreme UV light. In general, transparency to extreme UV light hardly depends on the substituents of the polymer, but relatively largely depends on the kinds of elements constituting the polymer. Carbon and hydrogen, which are main constituting elements of the polymer, absorb extreme UV light to such a small degree that the polymer can be transparent enough to achieve the effect of the present invention. The topcoat layer has transmittance of preferably 80% or more, further preferably 85% or more to extreme UV light at 13.5 nm. On the other hand, the topcoat layer formed in the above manner is poorly transparent to deep UV light, and hence has transmittance of preferably 20% or less, further preferably 15% or less to deep UV light at 248 nm.

Thereafter, the resist layer is subjected to exposure through a mask according to necessity by use of extreme UV light (for example, in the wavelength range of 5 to 20 nm, particularly, at 13.5 nm).

After the exposure, the resist layer is subjected to after-exposure heating, if necessary, and then developed in the manner of, for example, paddle development, to form a resist pattern. The development is normally carried out by use of an alkali developer. Since the composition of the present invention for forming a topcoat layer contains the water-soluble polymer comprising hydrophilic groups, the topcoat layer is easily removed by the developer.

The above means that, in the present invention, both removal of the topcoat layer and development of the resist layer can be conducted with an alkali developer at the same time without exceptional procedures. However, the topcoat layer may be alone removed with an aqueous solvent such as water, and then the resist layer can be independently developed with an alkali developer.

Examples of the alkali developer include aqueous solutions of sodium hydroxide and tetramethyl-ammonium hydroxide (TMAH). After the development, the resist pattern is rinsed (washed), if necessary, with a rinse solution, preferably, pure water. The resist pattern thus formed is employed as a resist for etching, plating, ion diffusion or dyeing, and then, if necessary, peeled away.

The thickness of the resist pattern is suitably determined according to the use and the like, but is normally 0.1 to 150 nm, preferably 20 to 80 nm.

The resist pattern thus formed by the pattern formation method of the present invention is then fabricated according to the use. The pattern formation method of the present invention does not particularly restrict the fabrication, and hence the resist pattern can be fabricated in a conventional manner

The present invention is further explained by use of the following Examples.

### Examples 101 to 117

Vinyl monomers having various substituents were polymerized in such combinations as shown in Table 1, to obtain water-soluble polymers. Each polymer was dissolved in pure water or in a mixed solvent of water/iso-propanol (content of iso-propanol: 30 wt %) so that the polymer content might be 3 wt %, to prepare each composition for forming a topcoat layer.

Independently, a substrate was spin-coated with a resist composition in a thickness of 50 nm. The resist composition was AZ AX2110, AZ DX5240 or AZ DX7260 ([trademark], all of which were manufactured by AZ Electronic Materials (Japan) K.K.). After the resist composition was cast on the substrate, each composition for forming a topcoat layer was spread thereon by spin-coating in a thickness of 30 nm. The layered compositions were then heated at 120° C. for 60 seconds to obtain a resist layer covered with a topcoat layer.

The resist layer thus formed was developed for 30 seconds with a 2.38% aqueous solution of tetramethyl-ammonium hydroxide, and then the surface was observed to evaluate whether or not residues were left thereon. The results were shown in Table 1.

TABLE 1

| | | monomers for water-soluble polymer | | | | | | | | | | | | | | | | | |
|---|---|---|---|---|---|---|---|---|---|---|---|---|---|---|---|---|---|---|---|
| | | monomers having | | | | | | | monomers having | | | | | | | | | | |
| | | deep-UV absorbing | | | | | | | hydrophilic groups | | | | | | | | | | residues |
| | | groups (mol %) | | | | | | | (mol %) | | | | | | | | | Resist | on the |
| Example No. | | A1 | A2 | A3 | A4 | A5 | A6 | A7 | B1 | B2 | B3 | B4 | B5 | B6 | B7 | B7 | solvent | Reson | surface |
| 101 | Example | 20 | | | | | | | 80 | | | | | | | | H₂O/IPA | AZ AZ2110 | no |
| 102 | Example | 20 | | | | | | | 80 | | | | | | | | H₂O/IPA | AZ DX5240 | no |
| 103 | Example | 20 | | | | | | | 80 | | | | | | | | H₂O/IPA | AZ DX7260 | no |
| 104 | Example | 10 | 10 | | | | | | 80 | | | | | | | | H₂O | AZ DX7260 | no |
| 105 | Example | 20 | | | | | | | 60 | 20 | | | | | | | H₂O | AZ DX7260 | no |
| 106 | Example | 10 | 10 | | | | | | 70 | 10 | | | | | | | H₂O | AZ DX7260 | no |
| 107 | Example | 10 | 10 | | | | | | 60 | 10 | 10 | | | | | | H₂O | AZ DX7260 | no |
| 108 | Example | 10 | | | | | | | 60 | | 10 | 10 | 10 | | | | H₂O | AZ DX7260 | no |
| 109 | Example | 10 | 10 | | | | | | 60 | | | 20 | | | | | H₂O | AZ DX7260 | no |
| 110 | Example | | 10 | 10 | | | | | 65 | 15 | | | | | | | H₂O | AZ DX7260 | no |
| 111 | Example | | | 10 | 10 | | | | 60 | | | 20 | | | | | H₂O | AZ DX7260 | no |
| 112 | Example | | | | 10 | 10 | | | 60 | | | 20 | | | | | H₂O | AZ DX7260 | no |
| 113 | Example | | | | 10 | | 10 | | 60 | | | 20 | | | | | H₂O | AZ DX7260 | no |
| 114 | Example | | | | | | | 20 | 60 | | | 20 | | | | | H₂O | AZ DX7260 | no |
| 115 | Example | 10 | | | 10 | | | | | | | | 40 | 40 | | | H₂O | AZ DX7260 | no |
| 116 | Example | 10 | | | 10 | | | | | | | | | 40 | 40 | | H₂O | AZ DX7260 | no |
| 117 | Example | 10 | | | 10 | | | | | | | | | 40 | | 40 | H₂O | AZ DX7260 | no |
| 118 | Comparison | 30 | 70 | | | | | | | | | | | | | | Xylene | AZ DX7260 | left |

Monomers in Table 1 were as follows:

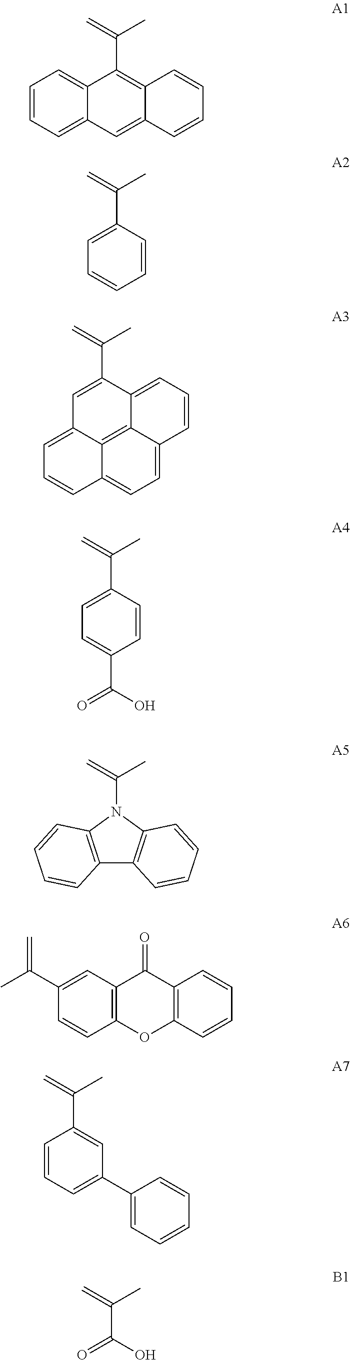

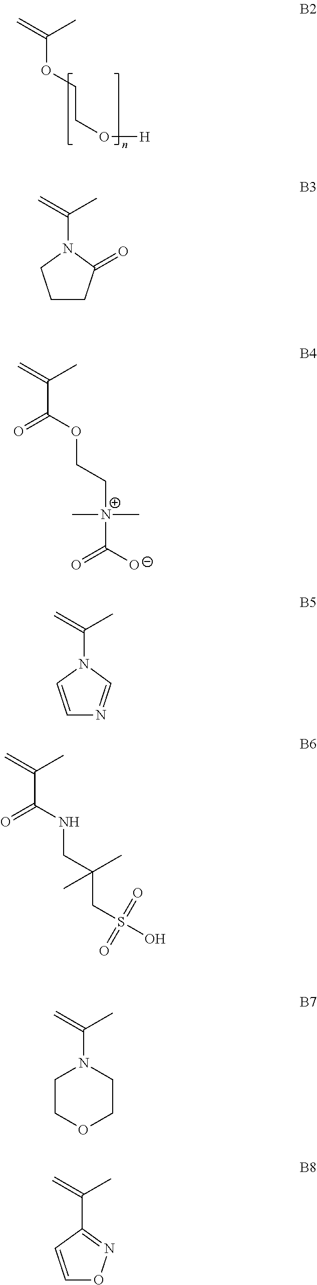

### Examples 201 to 216

Vinyl monomers having various substituents were polymerized in such combinations as shown in Table 2, to obtain water-soluble polymers. Each polymer was dissolved in pure water or in a mixed solvent of water/iso-propanol (content of iso-propanol: 30 wt %) so that the polymer content might be 3 wt %, to prepare each composition for forming a topcoat layer.

Independently, a substrate was spin-coated with a resist composition in a thickness of 50 nm. The resist composition was AZ EXR-015 ([trademark], manufactured by AZ Electronic Materials (Japan) K.K.). After the resist composition was cast on the substrate, each composition for forming a topcoat layer was spread thereon by spin-coating in a thickness of 30 nm. The layered compositions were then heated at 120° C. for 60 seconds to obtain a resist layer covered with a topcoat layer. In Example 201, however, the topcoat layer was not formed for the sake of comparison.

The resist layer thus formed was subjected to exposure by use of a BL03 beam from Spring-8 at the illuminance of 0.35 mW/cm², and then developed for 30 seconds with a 2.38% aqueous solution of tetramethyl-ammonium hydroxide. In that way, the exposure amount necessary for forming a pattern, namely, the energy threshold Eₜₕ was measured. The results were shown in Table 2.

TABLE 2

| | | monomers for water-soluble polymer | | | | | | | | | | | | | | | | | |
|---|---|---|---|---|---|---|---|---|---|---|---|---|---|---|---|---|---|---|---|
| | | monomers having | | | | | | | monomers having | | | | | | | | | | |
| | | deep-UV absorbing | | | | | | | hydrophilic groups | | | | | | | | | | |
| | | groups (mol %) | | | | | | | (mol %) | | | | | | | | | Resist | Eₜₕ |
| Example No. | | A1 | A2 | A3 | A4 | A5 | A6 | A7 | B1 | B2 | B3 | B4 | B5 | B6 | B7 | B7 | solvent | Reson | (mJ/cm²) |
| 201 | Example | | | | 100 | | | | | | | | | | | | H₂O/IPA | AZ EXR-015 | 7 |
| 202 | Example | 20 | | | | | | | 80 | | | | | | | | H₂O | AZ EXR-015 | 7 |
| 203 | Example | 20 | | | | | | | 60 | 20 | | | | | | | H₂O | AZ EXR-015 | 8 |
| 204 | Example | 10 | 10 | | | | | | 70 | 10 | | | | | | | H₂O | AZ EXR-015 | 6 |
| 205 | Example | 10 | 10 | | | | | | 60 | 10 | 10 | | | | | | H₂O | AZ EXR-015 | 8 |
| 206 | Example | 10 | | | | | | | 60 | | 10 | 10 | 10 | | | | H₂O | AZ EXR-015 | 7 |
| 207 | Example | 10 | 10 | | | | | | 60 | | | 20 | | | | | H₂O | AZ EXR-015 | 8 |
| 208 | Example | | 10 | 10 | | | | | 65 | 15 | | | | | | | H₂O | AZ EXR-015 | 7 |
| 209 | Example | | | 10 | 10 | | | | 60 | | | 20 | | | | | H₂O | AZ EXR-015 | 7 |
| 210 | Example | | | | 10 | 10 | | | 60 | | | 20 | | | | | H₂O | AZ EXR-015 | 8 |
| 211 | Example | | | | 10 | | 10 | | 60 | | | 20 | | | | | H₂O | AZ EXR-015 | 9 |
| 212 | Example | | | | | | | 20 | 60 | | | 20 | | | | | H₂O | AZ EXR-015 | 5 |
| 213 | Example | 10 | | | 10 | | | | | | | | 40 | 40 | | | H₂O | AZ EXR-015 | 6 |
| 214 | Example | 10 | | | 10 | | | | | | | | | 40 | 40 | | H₂O | AZ EXR-015 | 7 |
| 215 | Example | 10 | | | 10 | | | | | | | | | 40 | | 40 | H₂O | AZ EXR-015 | 6 |
| 216 | Comparison | | | | | | | | 100 | | | | | | | | H₂O | AZ EXR-015 | 8* |

### Examples 301 to 319

The procedure of Example 201 was repeated to form patterns. In this procedure, the pressure in the exposure chamber was measured before and after exposure to extreme UV light, to obtain the pressure difference AP between them. Further, same procedure was repeated except that the content of the composition was changed. The results were shown in Table 3.

TABLE 3

| | | monomers for water-soluble polymer | | | | | | | | | | | | | | | | | |
|---|---|---|---|---|---|---|---|---|---|---|---|---|---|---|---|---|---|---|---|
| | | monomers having | | | | | | | monomers having | | | | | | | | | | |
| | | deep-UV absorbing | | | | | | | hydrophilic groups | | | | | | | | | | |
| | | groups (mol %) | | | | | | | (mol %) | | | | | | | | | Resist | ΔP |
| Example No. | | A1 | A2 | A3 | A4 | A5 | A6 | A7 | B1 | B2 | B3 | B4 | B5 | B6 | B7 | B7 | solvent | Reson | (×10⁻⁷ Pa) |
| 301 | Comparison | The topcoat layer was not formed. | | | | | | | | | | | | | | | | AZ EXR-015 | 17.0 |
| 302 | Comparison | | 100 | | | | | | | | | | | | | | Xylene | AZ EXR-015 | 13.0 |
| 303 | Example | | | | 100 | | | | | | | | | | | | H₂O/ | AZ EXR-015 | 7.20 |
| | | | | | | | | | | | | | | | | | IPA | | |
| 304 | Example | 20 | | | | | | | 80 | | | | | | | | H₂O | AZ EXR-015 | 5.60 |
| 305 | Example | 20 | | | | | | | 60 | 20 | | | | | | | H₂O | AZ EXR-015 | 4.00 |
| 306 | Example | 10 | 10 | | | | | | 70 | 10 | | | | | | | H₂O | AZ EXR-015 | 5.00 |
| 307 | Example | 10 | 10 | | | | | | 60 | 10 | 10 | | | | | | H₂O | AZ EXR-015 | 7.00 |
| 308 | Example | 10 | | | | | | | 60 | | 10 | 10 | 10 | | | | H₂O | AZ EXR-015 | 7.00 |
| 309 | Example | 10 | 10 | | | | | | 60 | | | 20 | | | | | H₂O | AZ EXR-015 | 6.00 |
| 310 | Example | | 10 | 10 | | | | | 65 | 15 | | | | | | | H₂O | AZ EXR-015 | 5.00 |
| 311 | Example | | | 10 | 10 | | | | 60 | | | 20 | | | | | H₂O | AZ EXR-015 | 6.00 |
| 312 | Example | | | | 10 | 10 | | | 60 | | | 20 | | | | | H₂O | AZ EXR-015 | 5.50 |
| 313 | Example | | | | 10 | | 10 | | 60 | | | 20 | | | | | H₂O | AZ EXR-015 | 6.00 |
| 314 | Example | | | | | | | 20 | 60 | | | 20 | | | | | H₂O | AZ EXR-015 | 8.00 |
| 315 | Example | 10 | | | 10 | | | | | | | | 40 | 40 | | | H₂O | AZ EXR-015 | 6.00 |
| 316 | Example | 10 | | | 10 | | | | | | | | | 40 | 40 | | H₂O | AZ EXR-015 | 5.00 |
| 317 | Example | 10 | | | 10 | | | | | | | | | 40 | | 40 | H₂O | AZ EXR-015 | 7.00 |
| 318 | Comparison | 30 | 70 | | | | | | | | | | | | | | Xylene | AZ EXR-015 | 14.00 |
| 319 | Comparison | | | | | | | | 100 | | | | | | | | H₂O | AZ EXR-015 | 4.00 |

Table 3 indicates that Examples according to the present invention exhibited smaller pressure differences than Example 301, in which the topcoat layer was not provided, and Example 318, in which the polymer comprised no hydrophilic groups. Accordingly, the results suggest that outgassing was well prevented by the topcoat layers according to the present invention.

### Examples 401 to 403

The procedure of Example 204 was repeated except that the composition for forming a topcoat layer was spin-coated in different rotation speeds so as to change the thickness of the resultant topcoat layer. The energy threshold Eₜₕ of each obtained sample was measured in the same manner as in Example 204. The results were shown in Table 4.

TABLE 4

| | | Thickness of | |
|---|---|---|---|
| | | the topcoat | Eₜₕ |
| Example No. | | layer (nm) | (mJ/cm²) |
| 401 | Example | 10 | 6 |
| 402 | Example | 20 | 6 |
| 403 | Example | 30 | 6 |

The results of Examples 401 to 403 indicate that the sensitivity was hardly affected even if the thickness of the topcoat layer was changed.

### Examples 501 to 506

A water-soluble polymer was synthesized by polymerizing 20 mol % of A1 and 20 mol % of A2 as the monomers having deep-UV absorbing groups and 50 mol % of B1 and 10 mol % of B2 as the monomers having hydrophilic groups. The obtained polymer was dissolved in a water/iso-propanol mixed solvent, in iso-propanol or in PGMEA so that the content of the polymer might be 3 wt %, to prepare a composition for forming a topcoat layer.

Independently, a substrate was spin-coated with a resist composition AZ DX7260 ([trademark], manufactured by AZ Electronic Materials (Japan) K.K.) in a thickness of 50 nm. After the resist composition was cast on the substrate, each composition for forming a topcoat layer was spread thereon by spin-coating in a thickness of 30 nm. The layered compositions were then heated at 120° C. for 60 seconds to obtain a resist layer covered with a topcoat layer. The obtained resist layer was observed to evaluate whether the thickness changed or not. Nanospec M6100 (Tradename, available from Nanometorics Japan K.K.) was used for the evaluation. The results were shown in Table 5. In the column “Resist Thickness” of this Table, “changed” means that the change ratio of the film thickness is 10% or more, and “not changed” means that the change ratio of the film thickness is less than 10%.

TABLE 5

| | | Ratio of solvents | | | |
|---|---|---|---|---|---|
| | | (weight %) | | | Resist |
| Example No. | | H₂O | IPA | PGMEA | Thickness |
| 501 | Comparison | — | — | 100 | changed |
| 502 | Comparison | — | 100 | — | changed |
| 503 | Comparison | 50 | 50 | — | changed |
| 504 | Example | 40 | 30 | — | not changed |
| 505 | Example | 80 | 20 | — | not changed |
| 506 | Example | 90 | 10 | — | not changed |

The results suggest that aqueous solvents comprising 70 weight % or more of the solvent prevented the resist layer from changing the thickness. Accordingly, it was verified that the composition of the present invention for forming a topcoat layer, which contains water as a solvent, gave excellent effects.

1. A composition for forming a topcoat layer on the top surface of a resist layer, containing
a water-soluble polymer comprising hydrophilic groups and deep-UV absorbing groups that absorb light in the wavelength range of 170 to 300 nm, and
an aqueous solvent,
wherein said aqueous solvent comprises 70 weight % or more of water based on the total weight of said aqueous solvent.

2. The composition for forming a topcoat layer according to claim 1, wherein said water-soluble polymer is a copolymer that comprises repeating units having the hydrophilic groups and other repeating units having the deep-UV absorbing groups.

3. The composition for forming a topcoat layer according to claim 1, wherein said deep-UV absorbing groups are selected from the group consisting of substituted phenyl groups, unsubstituted phenyl groups, substituted naphthyl groups, unsubstituted naphthyl groups, substituted anthracenyl groups, and unsubstituted anthracenyl groups.

4. The composition for forming a topcoat layer according to claim 1, wherein said hydrophilic groups are selected from the group consisting of hydroxyl, carboxyl, sulfo, substituted amino groups, unsubstituted amino groups, substituted ammonium groups, unsubstituted ammonium groups, carboxylic acid ester groups, sulfonic acid ester groups, substituted amide groups, unsubstituted amide groups, and oxime groups.

5. The composition for forming a topcoat layer according to claim 1, wherein said water-soluble polymer is represented by the following formula (I): 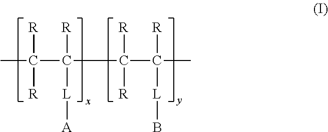
wherein
A is a deep-UV absorbing group; B is a hydrophilic group;
each R is independently hydrogen or a hydrocarbon group of 1 to 3 carbon atoms provided that plural Rs may be the same or different from each other;
each L is independently a divalent linking group provided that plural Ls may be the same or different from each other; and
each of x and y is a number indicating the molar ratio of each repeating unit.

6. The composition for forming a topcoat layer according to claim 1, wherein said water-soluble polymer is contained in an amount of 0.01 to 10 wt % based on the total weight of the composition.

7. A pattern formation method comprising the steps of:
casting a resist composition on a substrate, to form a resist layer, coating the resist layer with the composition for forming a topcoat layer according to claim 1,
heating to harden the composition for forming a topcoat layer,
subjecting the resist layer to exposure by use of extreme UV light, and
developing the exposed resist layer.

8. The pattern formation method according to claim 7, wherein said extreme UV light is in the wavelength range of 5 to 20 nm.

9. The pattern formation method according to claim 8, wherein a topcoat layer of 1 to 100 nm thickness is formed.

10. The pattern formation method according to claim 7, wherein the composition for forming a topcoat layer is heated to harden at a temperature of 25 to 150° C.

11. The composition for forming a topcoat layer according to claim 5 where the linking group L is chosen from single bond, ether bond, imide bond, amide bond or carboxylato bond.

12. The composition for forming a topcoat layer according to claim 5 where A, the deep-UV absorbing group, is a deep-UV absorbing group selected the group consisting of; 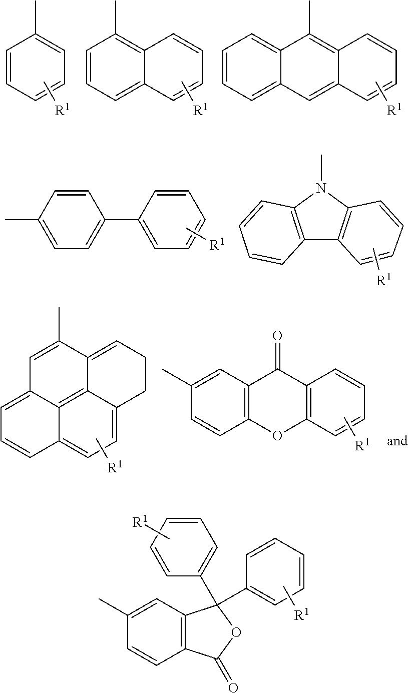
where R¹ is a substituent selected from the group consisting of hydrogen, hydrocarbon groups, hydroxyl and carboxyl.

13. The composition for forming a topcoat layer according to claim 5 where B, the hydrophilic group, is the hydrophilic group selected from the group consisting of; 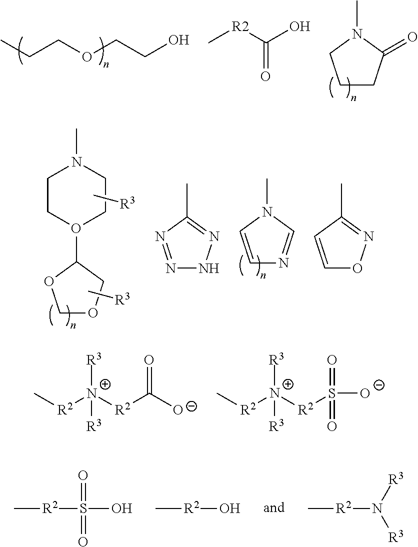
where R², is a divalent linking group selected from the group consisting of; single bond, substituted or unsubstituted hydrocarbon chain, ether bond, amide bond and ester bond; and R³, is independently, a substituent selected from the group consisting of hydrogen, hydrocarbon groups, hydroxyl and carboxyl.

14. The composition for forming a topcoat layer according to claim 1 where the water soluble polymer is 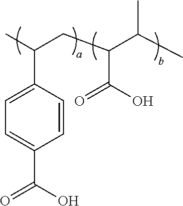
where each of a, and b is a number indicating the molar ratio of each repeating unit.

15. The composition for forming a topcoat layer according to claim 1 where the water soluble polymer is 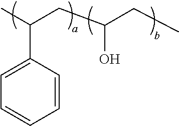
where each of a, and b is a number indicating the molar ratio of each repeating unit.

16. The composition for forming a topcoat layer according to claim 1 where the water soluble polymer is 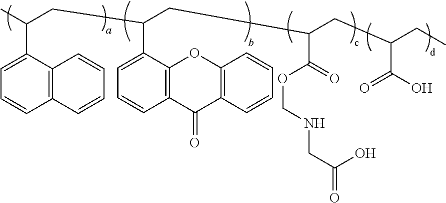
where each of a, b, c, and d is a number indicating the molar ratio of each repeating unit.

17. The composition for forming a topcoat layer according to claim 1 where the water soluble polymer is 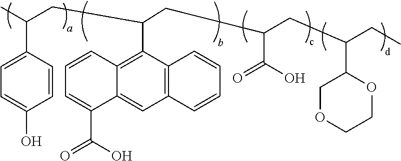
where each of a, b, c, and d is a number indicating the molar ratio of each repeating unit.

18. The composition for forming a topcoat layer according to claim 1 where the water soluble polymer is 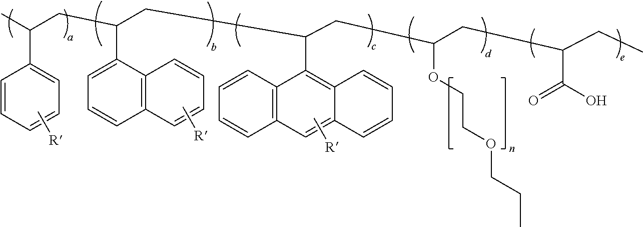
where R′ is hydrogen, a hydrocarbon group, hydroxyl, carboxyl or amino; each of a, b, c, d and e is a number indicating the molar ratio of each repeating unit;
and n represents a degree of polymerization.

19. The composition for forming a topcoat layer according to claim 1 where the water soluble polymer is 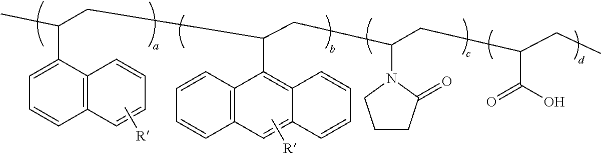
where R′ is hydrogen, a hydrocarbon group, hydroxyl, carboxyl or amino; each of a, b, c, and d is a number indicating the molar ratio of each repeating unit.

20. The composition for forming a topcoat layer according to claim 1 where the water soluble polymer is 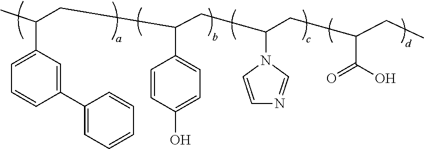
where each of a, b, c, and d is a number indicating the molar ratio of each repeating unit.
